(19) United States
(12) Patent Application Publication
(10) Pub. No.: US 2011/0317841 A1
(43) Pub. Date: Dec. 29, 2011

(54) METHOD AND DEVICE FOR OPTIMIZING AUDIO QUALITY

(76) Inventor: Lloyd Trammell, Houston, TX (US)

(21) Appl. No.: 12/824,130

(22) Filed: Jun. 25, 2010

(51) Int. Cl. H04R 5/00; H04R 1/40; H03G 3/00

(52) U.S. Cl. 381/18; 381/107; 381/17; 381/97

(57) ABSTRACT

A computer-implemented method is disclosed for enhancing quality of an audio source. The method comprises receiving control information; receiving an initial signal from the audio source; and generating a dynamic control signal based on the control information. The control information includes attack, release, length, and gain parameters.

### BACKGROUND OF THE INVENTION

This invention relates to a method and device for optimizing an audio source.

Audio systems currently available, including those claimed to possess high fidelity features (or Hi-Fi, referring to reproduction of sound or images with minimal noise and distortion), fail to provide the listener with a realism experience, i.e., for the listener to feel personally situated in the original sound field. Conventional attempts at enhancing audio reproduction quality have included use of a “static” form of sound enhancement, namely, improving certain parameters, such as amplitude or frequencies, based on predetermined settings. Such techniques are disclosed in, for example, U.S. Patent Publication No. 2008/0008324, assigned to Creative Technology Ltd.

Another conventional sound enhancement technique is described in U.S. Patent Publication No. 2009/0190766 and U.S. Pat. No. 5,970,152, both assigned to SRS Labs, Inc. According to this technique, a group of multi-channels are received, which provide a simulated sound environment through playback of output signals. Though possibly capable of creating a surrounding ambience, this approach requires that input signals be collected from a plurality of sound sources, thus increasing complexity and burden of the original recording. Moreover, multiple speakers or amplifiers are needed for playback of such audio processing mechanism, which can affect consistency of sound quality. Accordingly this technique suffers from shortcomings resulting from its flexibility, portability and consistency.

In addition, many of the foregoing conventional approaches lack dynamic user interaction features and thus are incapable of dynamic enhancements based on user's preferences or needs or the particular features of the environment of the sound source.

Further, they are “static” for failing to dynamically react to varying signals under different circumstances and adjust the output audio according to the input signal's parameters, such as frequency, phase, and amplitude. By way of example, if a user sets treble level at +5, and bass level at −2 in the conventional system, it processes all input audio by the same criteria regardless of the input's parameters. In other words, “static” audio techniques adopt the same criteria to modify all input signals to the same extent, without variations in response to the audio input.

As a result, “static” techniques cannot correct or cancel phase shifts and/or distortions that occur during the audio recording and transmission process. In fact those techniques result in a deterioration of phase shifts and cause distortions due to their inability to automatically adjust parameter settings. These conventional techniques are thus unlikely to minimize noise and disharmony generated in signal processing, such as square wave phenomena, i.e., non-sinusoidal waveform, typically sounding hollow or distorted that often results in ear fatigue. Accordingly, such techniques are incapable of optimizing audio quality by enhancing acoustic accuracy.

Still other conventional sound processing techniques, such as compression formats MPEG-1 Audio Layer 3 (MP3) or Windows Media Audio (WMA) suffer from loss of sound quality from the original audio source resulting from undergoing the conversion process to a compact file. Compressing or compacting methods in existence today inevitably result in phase and frequency anomalies. Furthermore, such conventional techniques suffer from other deficiencies, such as the inability of the compressed files to be reconstructed to their original sonic quality and permanent loss of the fidelity and accuracy for certain frequencies of the original sound resulting from compression. Other deficiencies associated with these techniques include destructive effects, which often occur during the compressing process, with no conventional measure available to reverse or improve the audio parameters while minimizing the file size or transmission channel bandwidth.

### SUMMARY OF THE INVENTION

Given the above deficiencies of prior art, there is a need for an audio-enhancing method or apparatus which imparts to the listener a realism feel of being personally situated in the sound field that existed during the live recording of the audio. The present invention achieves this goal by way of an “audio-enhancing module,” described herein.

The inventive audio-enhancing module of the present invention is capable of dynamically enhancing the quality in the audio output by modifying the parameters thereof in response to various input signals, thereby minimizing disharmony and distortion noise to create the interacting, realism-imparting sound fields.

Additionally, the present invention provides the user with full control over the resulting sound from the audio-enhancing module, thereby “dynamically” changing various parameters of the audio input to convert it into the desirable output. Further, the present invention is capable of addressing the fatigue and hearing loss defects that result from the conventional technologies, to optimize the output quality of the audio source.

The present invention is directed to a method and module for enhancement and optimization of audio quality. According to an aspect of the present invention, control information and an initial signal from an audio source are received and a control signal is generated based on the control information and the initial signal from the audio source.

The control information can include, for example, Attack, Release, Length and Gain.

Attack determines the speed at which the audio-enhancing module starts to react. Release determines the duration of stop before the Attack becomes active. Gain determines the amplitude of the output signal in dB units. Length adjusts the amount of audio data to be processed in one batch; According to its value, the audio-enhancing module determines to process a larger or smaller length of data at one time.

The phase of the initial signal is subsequently dynamically shifted in response to the control signal. The control signal determines the magnitude of the dynamic phase shift in proportion thereto within a range, in both positive and negative directions.

Preferably, the amplitude of the signal is dynamically modified according to the gain control information.

According to another aspect of the present invention, the signal that is being processed by the inventive method is one of the dual stereo signals derived from an audio signal of the audio source; and, following the processing, the two signals are blended into one.

Preferably, the dynamically phase-shifted signal is mixed with other dynamically phase-shifted signals to make the output signal more harmonic and pleasant. This control is dynamic, not static, in its operation and is constantly being changed according to the initial signal in both positive and negative directions.

In some implementations, the post-processed signal can be flipped in phase by 180°to cancel out some of the frequencies in the combined signal.

These and other features and advantages of this invention will become further apparent from the detailed description and accompanying figures that follow. In the figures and description, numerals indicate the various features of the invention, like numerals referring to like features throughout both the drawings and the description.

### BRIEF DESCRIPTION OF THE DRAWINGS

FIG. 1 illustrates an exemplary embodiment of the Audio-Enhancing Module according to the present invention.

FIG. 2 depicts various components integrated in the Left Processing Module embodying the present invention.

FIG. 3 illustrates an embodiment of the Filter Bank according to the present invention.

FIG. 4 is a block diagram of the Tube Simulator as preferably embodied according to the present invention.

FIG. 5 is a block diagram of the Sub Bass Enhancer according to the invention disclosed herein.

FIG. 6 is a block diagram showing various inputs being mixed in the Left Mono Mixer.

FIG. 7 is a block diagram of the Harmonic Octave Equalizer as preferably embodied in the current invention.

FIG. 8 is a block diagram of an exemplary architecture 800 that the present invention can be implemented upon.

### DETAILED DESCRIPTION OF THE PREFERRED EMBODIMENT(S)

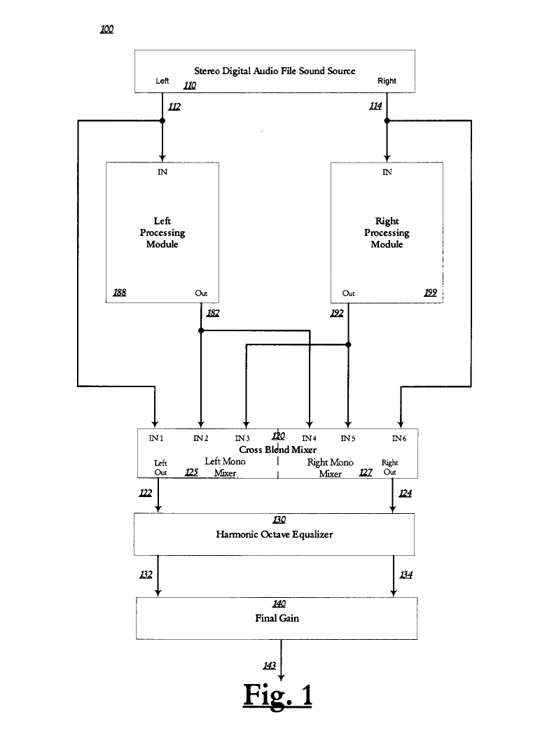

FIG. 1 illustrates an exemplary embodiment of the Audio-Enhancing Module 100 according to the present invention. The Audio-Enhancing Module 100 is advantageously implemented in a software process that runs on an information processing system such as a computer (such as desktop or laptop), pocket PC, personal digital assistants (PDA), mobile devices, and the like. The Audio Source 110 of the Audio-Enhancing Module 100 can be either analog or digital signal.

In some implementations, the Audio Source 110 is saved in the hard drive or memory of the computer or similar devices to be accessed and processed by the Audio-Enhancing Module 100. In other implementations, the Audio Source 110 is directly sent to the Audio-Enhancing Module 100 for processing.

If the Audio Source 110 is not already in the form of stereo, it is advantageously converted into two Stereo Signals 112, 114 upon entering the Audio-Enhancing Module 100, which subsequently sends the two Stereo Signals 112, 114 to Left Processing Module 188 and Right Processing Module 199, respectively. The two Processing Modules 188, 199 are preferably identical and each generate a control signal 182, 192 based on control information such as Attack, Release, Length and Gain, which is described in further details below.

Because the two Processing Modules 188 and 199 share identical structures and functions, the description that immediately follows focuses on the Left Processing Module 188 as an example.

The input signal of the Left Processing Module 188 (the Stereo Signal 112) is blended in Cross Blend Mixer 120 with the output signal of the Left Processing Module 188 (the Left Output 182) and the output signal from the Right Processing Module 199 (the Right Output 192) to create signal interaction and realism effects. The Cross Blend Mixer 120 consists of Left Mono Mixer 125 and Right Mono Mixer 127, which respectively handle the signals on the left side and right side, as shown in FIG. 1. The blending process of the Cross Blend Mixer 120 addresses the phase cancellation and reinforcement issues that are likely to have occurred in the Processing Modules 188, 199.

Optionally, the Output Signals 122, 124 of the Left Mono Mixer 125 and Right Mono Mixer 127 are corrected in frequencies by Harmonic Octave Equalizer 130 to create harmonic effects. The Harmonic Octave Equalizer 130 advantageously raises or lowers a range of frequencies symmetrically centering the central frequency of the Output Signals 132, 134.

Optionally, the Final Gain Control 140 component adjusts Output Signals 132, 134, by changing the gain up or down to generate the final output 142 of the Audio-Enhancing Module 100 for receiving by apparatuses such as sound cards, amplifier, speakers, and the like.

Table 1 provides an exemplary parameter setting used in the Final Gain Control 140 of the Audio-Enhancing Module 100 that applies to the generic “Rock & Roll” genre:

TABLE 1
FinalGainPct = 1.000000000

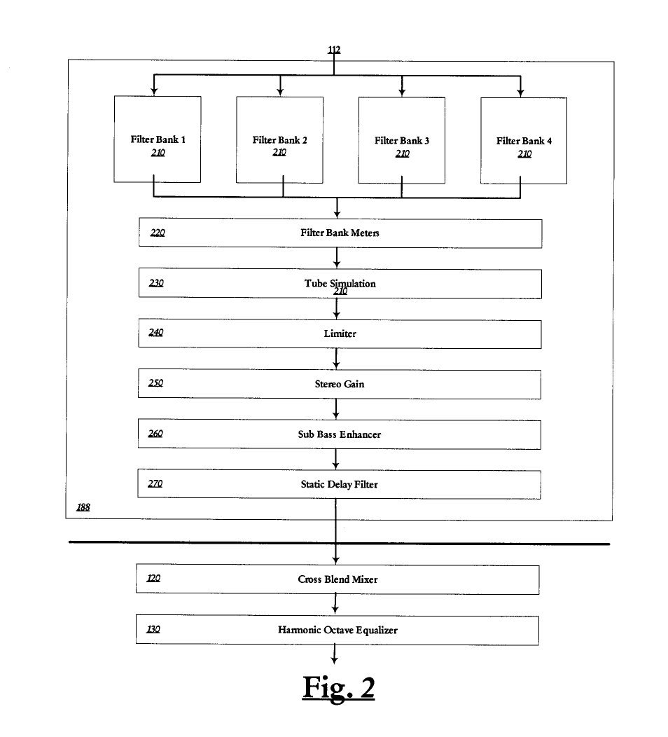

FIG. 2 depicts various components integrated in the Left Processing Module 188, which is a mirror diagram of the Right Processing Module 199. The Left Processing Module 188 preferably includes four Filter Banks 210, four Filter Bank Meters 220, one Tube Simulator 230, one Limiter 240, one Stereo Gain 250, one Sub Bass Enhancer 260, and one Static Delay Filter 270.

Advantageously, the four Filter Banks 210 are identical in structure and functions to control their output in a consistent fashion. The Filter Banks 210 are each dedicated to process a specific and different frequency range, for example, bass, mid-bass, treble, or high-treble. Each Filter Bank 210 works dynamically, i.e., monitoring the amplitude, phase and frequency of the received Stereo Signal 112 in respect to its designated frequency range.

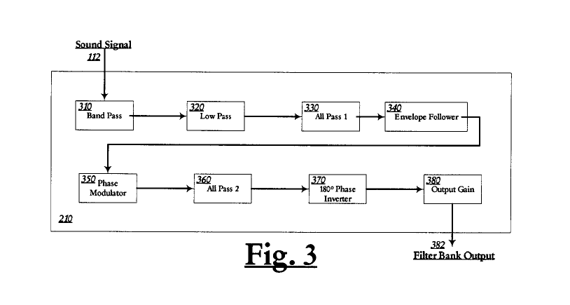

With reference to FIG. 3, which illustrates the details of the Filter Bank 210, each Filter Bank 210 encompasses a Band Pass Filter 310, a Low Pass Filter 320, an All Pass Filter (1) 330, an Envelope Follower 340, a Phase Modulator 350, an All Pass Filter (2) 360, a Phase Inverter 370, and an Output Gain 380.

The Band Pass Filter 310 receives the Stereo Signal 112 and controls frequency and bandwidth. The Band Pass Filter 310 allows only frequencies between two specific points to pass, thereby filtering noises outside of the chosen parameters of points. The bandwidth of the Band Pass Filter 310 is the frequency difference between the upper and lower cutoff points. The same effect that results from the Band Pass Filter 310 may also be created by combining a low pass filter with a high-pass filter. The specific frequency parameters or points can be either selected by a user via the user interface of the Audio-Enhancing Module 100 or predetermined by default thereof.

The Low Pass Filter 320 receives the Stereo Signal 112 from the Band Pass Filter 310 and controls frequency only; the Low Pass Filter 320 blocks frequencies above a specific point while allowing frequencies below that parameter or point to pass through. Like the Band Pass Filter 310, the specific frequency parameter or point can be either selected by a user via the user interface of the Audio-Enhancing Module 100 or predetermined by default thereof.

The All Pass Filter (1) 330 passes all frequencies equally, while changing the phase relationship among various frequencies of the Stereo Signal 112, which is being processed in the Filter Bank 210. This process compensates the Stereo Signal 112 for undesired phase that has occurred in the Left Processing Module 188, which could cause “quadrature” between the input and output signals, i.e., a quarter wavelength of delay there between. The All Pass Filter (2) 360 structures and functions similarly to the All Pass Filter (1) 330.

According to the present invention, the Envelope Follower 340 receives the Stereo Signal 122 from the All Pass Filter (1) 330 and controls Attack, Release, Length and Gain parameters.

Conventionally, an envelope follower is implemented on an electronic circuit and converts an original signal to its “envelope shape” as the output. A capacitor in the electronic circuit, for example, accumulates charge when the incoming amplitudes are rising. A resistor therein, for example, discharges when the incoming amplitudes are abating.

Attack determines the speed at which the Envelope Follower 340 starts to react. When the Attack is set high, the Envelope Follower 340 is more sensitive and starts in an instant; while the Attack is set low, the Envelope Follower 340 is less sensitive, thereby increasing an envelope slower depending on the level of the Attack.

Release determines the duration of stop before the Attack becomes active. More specifically, setting the Release high renders the duration long, while setting the release low renders the duration short.

Gain determines the output amplitude in dB of the Envelope Follower 340. When Gain is set at a high value, the output amplitude is increased by a higher ratio or scale. On the other hand, when Gain is set at a low value, the output amplitude is increased by a lower ratio or scale.

Length adjusts the amount of audio data to be processed in one batch. According to the value of Length, the audio-enhancing module determines to process a larger or smaller chunk of data at one time.

The foregoing four parameters can be determined based on user selections through the user interface; alternatively, the parameters can be pre-defined in the Audio-Enhancing Module 100.

The Phase Modulator 350 receives the Control Signal 182 that has been processed and output by the Envelope Follower 340; and is driven by the Gain amount set by the Envelope Follower 340. The Phase Modulator 350 increases or decreases an amount of phase shift dynamically in the Control Signal 182 passing therethrough. More specifically, the Phase Modulator 350 changes the phase angle of the envelope of the Control Signal 182, in direct proportion thereto.

Optionally, the Filter Bank 210 includes the Phase Inverter 360, which can be turned on and off. At the “on” status, the Phase Inverter 360 flips the Control Signal 182 in phase by 180 degree, in effect reversing the overall phase of the modification that has been done to the Control Signal 182.

Optionally, the Filter Bank 210 includes the Output Gain 380, which adds gain to the amplitude of the Control Signal 182 passing therethrough, in a scale from minimum to maximum of the Control Signal 182's amplitude.

The following Tables 2-5 provide an exemplary set of parameters used in the four Filter Banks 210 of the Left Processing Module 188 for “Rock & Roll” music:

TABLE 2

Filter Bank 1
BpWidth = 4406
BpFc = 1085
HighLowPassFc = 2000
Ap1Width = 20000
Ap1Fc = 10000
Ap2Width = 20000
Ap2Fc = 6980
AttackTime = 4.000000000
ReleaseTime = 8.000000000
EnvFolLenPct = 0.720000029
EnvelopeGain = 0.510000000
FinalGain = 0.890000000
PhaseShift = 0.660000026
PhaseInverted = NO

TABLE 3

Filter Bank 2
BpWidth = 14336
BpFc = 2143
HighLowPassFc = 4000
Ap1Width = 20000
Ap1Fc = 10000
Ap2Width = 20000
Ap2Fc = 10000
AttackTime = 27.000000000
ReleaseTime = 8.000000000
EnvFolLenPct = 0.689000010
EnvelopeGain = 0.970000000
FinalGain = 0.560000000
PhaseShift = 0.519999981
PhaseInverted = NO

TABLE 4

Filter Bank 3
BpWidth = 13523
BpFc = 4035
HighLowPassFc = 4000
Ap1Width = 20000
Ap1Fc = 10000
Ap2Width = 20000
Ap2Fc = 10000
AttackTime = 25.000000000
ReleaseTime = 13.000000000
EnvFolLenPct = 0.720000029
EnvelopeGain = 1.000000000
FinalGain = 0.780000000
PhaseShift = 0.509999990
PhaseInverted = YES

TABLE 5

Filter Bank 4
BpWidth = 18796
BpFc = 6750
HighLowPassFc = 7100
Ap1Width = 20000
Ap1Fc = 10000
Ap2Width = 20000
Ap2Fc = 10000
AttackTime = 25.000000000
ReleaseTime = 13.000000000
EnvFolLenPct = 0.720000029
EnvelopeGain = 1.000000000
FinalGain = 1.000000000
PhaseShift = 0.360000014
PhaseInverted = NO

Referring back to FIG. 2, the output of the Filter Bank 210 generated by the Left Processing Module 188, Filter Bank Output 382, is to be combined in the Filter Bank Meter 220 with the output signal of the corresponding Filter Bank of the Right Processing Module 199. The Filter Bank Meter 220 shows the amplitude of each pair of the output signals from the Filter Banks 210, i.e., one Filter Bank of the Left Processing Module 188 and its corresponding Filter Bank of the Right Processing Module 199. Preferably, the Filter Bank Meter 220 is capable of displaying the amplitude of all pairs of the output signals of the Filter Banks 210.

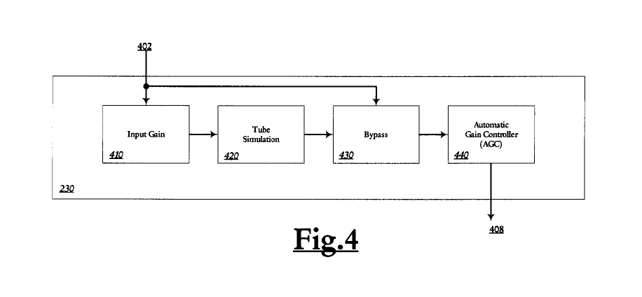

The Tube Simulator 230 receives the output signals directly from the Filter Banks 210, or alternatively, the output signals from the Filter Bank Meters 220 if connected directly thereto. In reference to FIG. 4, which illustrates various components and their functions within the Tube Simulator 230, the Tube Simulator 230 includes one Input Gain 410, one Tube Simulation 420, one Bypass 430, and one Automatic Gain Controller (AGC) 440.

The Input Gain 410 controls the gain of the Tube Input 402 received by the Tube Simulator 230. The Tube Simulation 420 has two controls: (1) threshold for simulating tube harmonics at different levels, which controls the amount of simulated soft clipping and the amount of added second order harmonics normally found in tubes; and (2) gain, which increases the amplitude of the Tube Output 408. The Bypass 430 turns the Tube Simulator 230 to “on” or “off” modes. In the “on” mode, the Tube Input 402 bypasses the path through the Input Gain 410 and Tube Simulation 420, and directly forwards to the AGC 440.

The AGC 440 sets the maximum level of a signal that is allowed to pass after the Tube Simulator 230, thereby minimizing noise or digital distortion. In common practice, the AGC 440 limits the amplitude of the signal in a range allowed to pass through it by feeding back the average output signal level. The AGC 440 process automatically reduces the volume of the signal when it's strong.

Table 6 exhibits an exemplary set of parameters used in the Tube Simulator 230 for the generic “Rock & Roll” type of music:

TABLE 6

MonoMixerGain = 0.520000000
TubeFilterGain = 0.960000000
TubeFilterThreshold = 0.310000002
TubeBypassed = NO

In reference back to FIG. 2, the Left Processing Module 188 optionally includes a Limiter 240, which controls the maximum level of a signal to pass therethrough. The Limiter 240 includes another automatic gain controller (not shown), which follows the Tube Simulator 230 in the signal path, to attenuate extreme signals to create a relatively concerted effect. The Stereo Gain 250 adds the amplitude gain to the signal processed therein.

Table 7 shows a parameter setting example for the Limiter 240 that applies to the “Rock & Roll” genre:

TABLE 7
StereoAgcOn = YES

Table 8 provides an exemplary setting used in the Stereo Gain 250 for the generic “Rock & Roll” type of music:

TABLE 8
StereoGain = 0.700000000

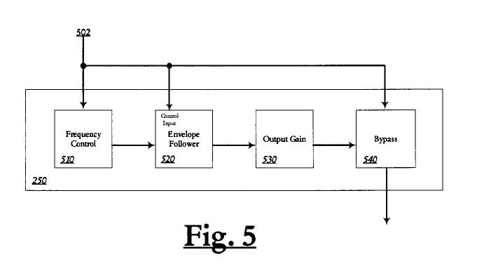

FIG. 5 is a block diagram of the Sub Bass Enhancer 260 included in the Left Processing Module 188 in accordance with the current invention. As illustrated in FIG. 5, the Sub Bass Enhancer 260 consists of a Frequency Control 510, an Envelope Follower 520, an Output Gain 530, and a Bypass 540.

Table 9 provides an exemplary series of settings used in the Sub Bass Enhancer 260 that cater for the “Rock & Roll” type of music:

TABLE 9

BassEnvelopeGain = 0.930000000
BassBypassed = NO
BassCenterFreq = 357.000000000
BassAttackTime = 9.000000000
BassReleaseTime = 8.000000000
BassEnvFolLenPct = 0.740000010

The Frequency Control 510 sets the center frequency in the Sub Bass Input 502. The Frequency Control sets the center, or main, frequencies of where this control will operate, which is similar to a variable bandpass with a +/− one octave bandwidth or window. The center frequency can be 50 Hz and 110 Hz, by way of example. The Envelope Follower 520 receives the Sub Bass Input 502 from the output of the Stereo Gain 250 and is similar to the Envelope Follower 340 as described above. The Envelope Follower 520 controls parameters, including the amplitude of the Sub Bass Input 502.

The Output Gain 530 sets the maximum amount of output gain for the Sub Bass Input 502. The Bypass 540 is provided to turn the Sub Bass Enhancer 260 on and off; when the Bypass 540 is on, the Sub Bass Input 502 does not travel through the Frequency Control 510, Envelope Follower 520, or Output Gain 530 and therefore leave the Sub Bass Enhancer 260 without being processed.

Referring back to FIG. 2, optionally connected to the Sub Bass Enhancer 260 in the signal path is the Static Delay Filter 270. The Static Delay Filter 270 selects an amount of delay to create special effects, such as combing filtering, and blends a selected amount of the delayed signal with the original signal as received in the Static Delay Filter 270.

Table 10 exhibits an example of parameter settings used in the Static Delay Filter 270 for the “Rock & Roll” type of music:

TABLE 10

DryBlendPct = 0.800000000
DelaySamples = 1

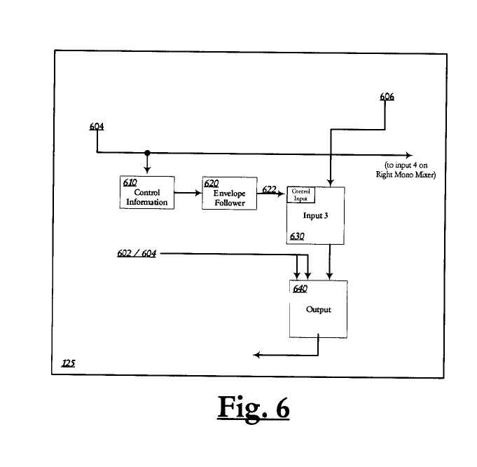

Out of the Left Processing Module 188 is the Cross Blend Mixer 120, which comprises the Left Mono Mixer 125 and Right Mono Mixer 127 in mirror images. FIG. 6 is a block diagram showing various inputs being mixed in the Left Mono Mixer 125. Input (1) 602 represents the Initial Stereo Signal 112 derived from the Audio Source 110. Input (2) 604 represents the Control Signal 182 that has been processed by the Left Processing Module 188. Input (3) 606 represents the Control Signal 192 that has been processed by the Right Processing Module 199.

In reference to FIG. 6, Control Information 610 reads the amplitude of the Input (2) 604 and controls its magnitude. The Input (2) 604 is subsequently processed by Envelope Follower 620, which controls a preferably predetermined amount of gain, e.g., 3%, to create a harmonic effect. The Envelope Follower 620 serves similar functions as the aforementioned Envelope Followers 340 and 520.

The output 622 of the Envelope Follower 620 is mixed in the Input 3 Module 630 with the Input (3) 606, which is the Control Signal generated from the opposite Processing Module, i.e., the Right Processing Module 199. Output Module 640 sets the maximum output level produced by the Left Mono Mixer 125.

Table 11 provides an exemplary parameter setting used in the Cross Blend Mixer 120 for the “Rock & Roll” genre:

TABLE 11

CrossBlendPct = 0.630000000

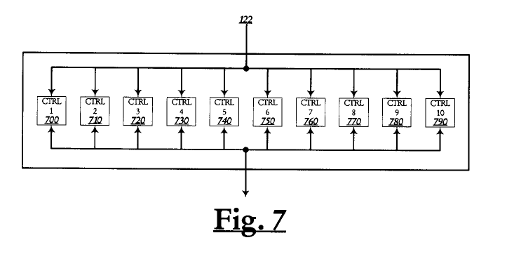

Referring back to FIG. 1, directly connected to the Cross Blend Mixer 120 is the Harmonic Octave Equalizer 130, whose more detailed embodiment is shown in FIG. 7. The Harmonic Octave Equalizer 130 controls levels with ten fixed Center Frequencies, marked with reference numerals 700-790 in FIG. 7. Each Center Frequency controls all of the harmonics associated with the center for the entire audio range proportionally as the Center Frequency is moved. By way of example, the Center Frequencies 700-790 consist of 60 Hz, 170 Hz, 310 Hz, 600 Hz, 1 kHz, 3 kHz, 6 kHz, 12 kHz, 14 kHz, and 16 kHz.

Table 12 provides an example of parameter settings used in the Harmonic Octave Equalizer 130 for the “Rock & Roll” type of music:

TABLE 12

Equalizer_0 = 0.700000000
Equalizer_1 = 0.910000000
Equalizer_2 = 0.840000000
Equalizer_3 = 0.720000000
Equalizer_4 = 0.550000000
Equalizer_5 = 0.750000000
Equalizer_6 = 0.830000000
Equalizer_7 = 0.940000000
Equalizer_8 = 0.910000000
Equalizer_9 = 0.930000000

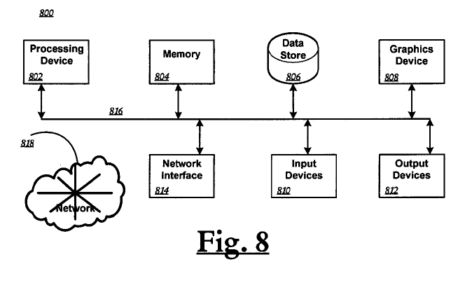

FIG. 8 is a block diagram of an exemplary architecture 800 that the present invention can be implemented upon. The example architecture 800 includes at least one processing device 802 coupled to a bus system 816 to transmit data, such as a data bus and a mother board. The example architecture 800 further includes the following units connected to the bus system 816: data store 806, memory 804, input device 810, output device 812, graphics device 808, and network interface 814.

The processing device 802 for executing programs or instructions can be or include general and special purpose microprocessors that incorporate functions of a central processing unit (CPU) on a single integrated circuit (IC). The CPU controls an operation of reading the information from the data store 806, for example.

The data store 806 or memory 804 both serve as computer data storage for the example architecture 800 to buffer or store data, temporarily and permanently. The computer data storage refers to computer components, devices, and recording media that retain digital data used for computing for some interval of time. The data store device 806 typically includes non-volatile storage device such as magnetic disks; magneto-optical disks; and CD-ROM and DVD-ROM disks. The memory 804 include all forms of non-volatile memory, including but not limited to semiconductor storage known as EPROM, EEPROM, flash memory devices, and dynamic random access memory, for example.

Examples for the input device 810 include a video camera, a keyboard, a mouse, a trackball, a stylus, etc.; and examples for output devices 812 can include a display device, an audio device, etc. The display monitors such as cathode ray tube (CRT) or liquid crystal display (LCD) monitor for displaying information to a user.

The graphics device 808 can, for example, include a video card, a graphics accelerator card, a graphics processing unit (GPU) or a display adapter, and is configured to generate and output images to a display device. In one implementation, the graphics device 808 can be realized in a dedicated hardware card connected to the bus system 816. In another implementation, the graphics device 808 can be realized in a graphics controller integrated into a chipset of the bus system 816.

The network interface 814 can, for example, include a wired or wireless network device operable to communicate data to and from a network 818. The network 818 may include one or more local area networks (LANs) or a wide area network (WAN), such as the Internet.

In one implementation, the system 800 includes instructions defining an operating system stored in the data store 806 and/or the memory 804. Example operating systems can include the MAC OS™ X series operating system, the WINDOWS™ based operating system, or other operating systems. Upon execution of the operating system instructions, access to various system objects is enabled. Example system objects include data files, applications, functions, windows, etc. To facilitate an intuitive user experience, the system 800 may include graphical user interface that provides the user access to the various system objects and conveys information about the system 800 to the user in an intuitive manner.

Having now described the invention in accordance with the requirements of the patent statutes, those skilled in this art will understand how to make changes and modifications in the present invention to meet their specific requirements or conditions. Such changes and modifications may be made without departing from the scope and spirit of the invention as set forth in the following claims.

What is claimed is:

1. A computer-implemented method for enhancing quality of an audio source, the method comprising:
receiving control information;
receiving an initial signal from the audio source; and
generating a dynamic control signal based on the control information, wherein the control information includes attack, release, length, and gain.

2. The method of claim 1, further comprising:
duplicating the initial signal into a plurality of signals, each dedicated to be processed in a specific frequency range different from that of the other signals.

3. The method of claim 2, wherein the plurality of signals comprises four duplicated signals.

4. The method of claim 1, further comprising:
monitoring the amplitude of the initial signal; and
modifying the amplitude of the initial signal according to the gain control information.

5. The method of claim 4, further comprising:
shifting the phase in the control signal according to the control signal itself.

6. The method of claim 5, wherein the magnitude of the dynamic phase shift is determined proportionally within a range.

7. The method of claim 5, further comprising:
flipping the dynamically phase-shifted signal in phase by 180 degree.

8. The method of claim 1, further comprising:
changing the phase relationship among various frequencies of the initial signal to compensate for phase anomaly.

9. The method of claim 5, further comprising:
adding gain to the amplitude of the dynamically phase-shifted signal, wherein the gain varies from zero to the full amplitude thereof.

10. The method of any of claims 2 and 5, further comprising:
mixing the dynamically phase-shifted signal with the plurality of signals that have dynamically shifted phases.

11. The method of claim 1, further comprising:
filtering out frequencies of the initial signal above a high frequency figure.

12. The method of claim 1, further comprising:
filtering out frequencies of the initial signal below a low frequency figure.

13. The method of any of claims 11 and 12, further comprising:
receiving user input to determine the high and low frequency figures.

14. The method of claim 5, further comprising:
changing the phase relationship among various frequencies of the dynamically phase-shifted signal to compensate for phase anomaly.

15. The method of claim 5, further comprising:
displaying the amplitude of the dynamically phase-shifted signal.

16. The method of claim 5, further comprising:
controlling threshold of the dynamically phase-shifted signal for simulating tube harmonics at different levels; and
controlling gain to the dynamically phase-shifted signal.

17. The method of claim 16, further comprising:
receiving user input to determine whether to bypass tube simulating of the dynamically phase-shifted signal.

18. The method of claim 16, further comprising:
feeding back output level of the dynamically phase-shifted signal to adjust gain for its input.

19. The method of claim 18, further comprising:
adding gain to the amplitude of the gain-adjusted, phase-shifted signal.

20. The method of claim 5, further comprising:
setting a center frequency of the dynamically phase-shifted signal for processing; and
further shifting the phase of the dynamically phase-shifted signal according thereto.

21. The method of claim 20, wherein the center frequency includes 50 Hz and 110 Hz.

22. The method of claim 5, further comprising:
selecting an amount of delay to create a special effect on the dynamically phase-shifted signal.

23. The method of claim 5, further comprising:
dividing an audio signal from the audio source into two identical initial signals; and
blending one of the initial signals with two dynamically phase-shifted signals that result from dynamically phase-shifting of the two initial signals.

24. The method of claim 23, further comprising:
controlling the output magnitude of the dynamically phase-shifted signals according to their input amplitude, respectively; and
adding gain to the output magnitude to create harmonic effect.

25. The method of claim 24, wherein the gain is predetermined as 3% of the input amplitude.

26. The method of claim 1, further comprising:
adjusting a range of frequencies symmetrically centering a central frequency of the control signal.

27. The method of claim 26, wherein the central frequency includes:
60 Hz, 170 Hz, 310 Hz, 600 Hz, 1 kHz, 3 kHz, 6 kHz, 12 kHz, 14 kHz, and 16 kHz.

28. The method of claim 1, further comprising:
adjusting gain up or down to the control signal to generate the final output.

29. A computer program product for enhancing quality of an audio source, encoded on a computer-readable medium, operable to cause one or more processors to perform operations comprising:
receiving control information;
receiving an initial signal from the audio source; and
generating a control signal based on the control information, wherein the control information includes attack, release, length, and gain.

30. The product of claim 29, wherein the operations further comprise:
duplicating the initial signal into a plurality of signals, each dedicated to be processed in a specific frequency range different from that of the other signals.

31. The product of claim 30, wherein the plurality of signals include four duplicated signals.

32. The product of claim 29, wherein the operations further comprise:
monitoring the amplitude of the initial signal; and
modifying the amplitude of the initial signal according to the gain control information.

33. The product of claim 32, wherein the operations further comprise:
shifting the phase in the control signal according to the control signal itself.

34. The product of claim 33, wherein the magnitude of the dynamic phase shift is determined proportionally within a range.

35. The product of claim 33, wherein the operations further comprise:
flipping the dynamically phase-shifted signal in phase by 180 degree.

36. The product of claim 29, wherein the operations further comprise:
changing the phase relationship among various frequencies of the initial signal to compensate for phase anomaly.

37. The product of claim 33, wherein the operations further comprise:
adding gain to the amplitude of the dynamically phase-shifted signal, wherein the gain varies from zero to the full amplitude thereof.

38. The product of any of claims 30 and 33, wherein the operations further comprise:
mixing the dynamically phase-shifted signal with the plurality of signals that have dynamically shifted phases.

39. The product of claim 29, wherein the operations further comprise:
filtering out frequencies of the initial signal above a high frequency figure.

40. The product of claim 29, wherein the operations further comprise:
filtering out frequencies of the initial signal below a low frequency figure.

41. The product of any of claims 39 and 40, wherein the operations further comprise:
receiving user input to determine the high and low frequency figures.

42. The product of claim 33, wherein the operations further comprise:
changing the phase relationship among various frequencies of the dynamically phase-shifted signal to compensate for phase anomaly.

43. The product of claim 33, wherein the operations further comprise:
displaying the amplitude of the dynamically phase-shifted signal.

44. The product of claim 33, wherein the operations further comprise:
controlling threshold of the dynamically phase-shifted signal for simulating tube harmonics at different levels; and
controlling gain to the dynamically phase-shifted signal.

45. The product of claim 44, wherein the operations further comprise:
receiving user input to determine whether to bypass tube simulating of the dynamically phase-shifted signal.

46. The product of claim 44, wherein the operations further comprise:
feeding back output level of the dynamically phase-shifted signal to adjust gain for its input.

47. The product of claim 46, wherein the operations further comprise:
adding gain to the amplitude of the gain-adjusted, phase-shifted signal.

48. The product of claim 33, wherein the operations further comprise:
setting a center frequency of the dynamically phase-shifted signal for processing; and
further shifting the phase of the dynamically phase-shifted signal according thereto.

49. The product of claim 48, wherein the center frequency includes 50 Hz and 110 Hz.

50. The product of claim 33, wherein the operations further comprise:
selecting an amount of delay to create a special effect on the dynamically phase-shifted signal.

51. The product of claim 33, wherein the operations further comprise:
dividing an audio signal from the audio source into two identical initial signals; and
blending one of the initial signals with two dynamically phase-shifted signals that result from dynamically phase-shifting of the two initial signals.

52. The product of claim 51, wherein the operations further comprise:
controlling the output magnitude of the dynamically phase-shifted signals according to their input amplitude, respectively; and
adding gain to the output magnitude to create harmonic effect.

53. The product of claim 52, wherein the gain is predetermined as 3% of the input amplitude.

54. The product of claim 29, wherein the operations further comprise:
adjusting a range of frequencies symmetrically centering a central frequency of the control signal.

55. The product of claim 54, wherein the central frequency includes:
60 Hz, 170 Hz, 310 Hz, 600 Hz, 1 kHz, 3 kHz, 6 kHz, 12 kHz, 14 kHz, and 16 kHz.

56. The product of claim 29, wherein the operations further comprise:
adjusting gain up or down to the control signal to generate the final output.
